(19) United States
(12) Patent Application Publication
(10) Pub. No.: US 2026/0211062 A1
(43) Pub. Date: Jul. 23, 2026

(54) MAGNETIC SENSOR DEVICE

(71) Applicant: TDK Corporation, Tokyo (JP)

(72) Inventors: Takehiro ISODA, Tokyo (JP); Norikazu OTA, Tokyo (JP)

(73) Assignee: TDK Corporation, Tokyo (JP)

(21) Appl. No.: 19/444,234

(22) Filed: Jan. 9, 2026

(30) Foreign Application Priority Data
Jan. 22, 2025 (JP) 2025-008889

(51) Int. Cl. G01R 33/09

(52) U.S. Cl. CPC G01R 33/09

(57) ABSTRACT

A support body includes at least one power supply pad and a ground pad. A first coil group includes a first end connected to the at least one power supply pad and a second end located at an end opposite to the first end. A second coil group includes a third end connected to the second end of the first coil group a fourth end located at an end opposite to the third end and connected to the ground pad. The number of the at least one power supply pad is equal to or less than the total number of at least one first coil and at least one second coil.

### CROSS-REFERENCE TO RELATED APPLICATION

This application claims the benefit of Japanese Priority Patent Application No. 2025-008889 filed on Jan. 22, 2025, the entire contents of which are incorporated herein by reference.

### BACKGROUND

The disclosure relates to a magnetic sensor device.

International Publication No. WO 2019/131812 describes a magnetic sensor module and an IC chip used therein. Japanese Unexamined Patent Application Publication No. 2016-102751 discloses a magnetic sensor and a current amount detector. Japanese Unexamined Patent Application Publication No. 2017-504018 discloses a push-pull bridge magnetic sensor. Japanese Unexamined Patent Application Publication No. 2021-085738 discloses a magnetic sensor. Japanese Unexamined Patent Application Publication No. 2021-148625 discloses a magnetic sensor device.

However, International Publication No. WO 2019/131812, Japanese Unexamined Patent Application Publication No. 2016-102751, Japanese Unexamined Patent Application Publication No. 2017-504018, Japanese Unexamined Patent Application Publication No. 2021-085738, and Japanese Unexamined Patent Application Publication No. 2021-148625 each have room for improvement in terms of reduction in size and suitability for an operation under an environmental magnetic field (for example, in appropriately performing set/reset operations and self-test operations).

### SUMMARY

A magnetic sensor device according to one embodiment of the disclosure includes a first chip including a plurality of first magnetoresistive elements, a second chip including a plurality of second magnetoresistive elements, a support body that supports the first chip and the second chip, a first coil group including at least one first coil configured to apply a magnetic field to the plurality of first magnetoresistive elements, and a second coil group including at least one second coil configured to apply a magnetic field to the plurality of second magnetoresistive elements. The support body includes at least one power supply pad and a ground pad. The first coil group includes a first end connected to the at least one power supply pad, and a second end located at an end opposite to the first end. The second coil group includes a third end connected to the second end of the first coil group, and a fourth end located at an end opposite to the third end and connected to the ground pad. The number of the at least one power supply pad is equal to or less than the total number of the at least one first coil and the at least one second coil.

A magnetic sensor device according to an embodiment of the disclosure includes a chip including a plurality of magnetoresistive elements, a support body that supports the chip, and a coil group including a plurality of coils configured to apply a magnetic field to the plurality of magnetoresistive elements. The support body includes at least one power supply pad and a ground pad. The coil group includes a first end connected to the at least one power supply pad, and a second end located at an end opposite to the first end and connected to the ground pad. The number of the at least one power supply pad is equal to or less than the total number of the plurality of coils.

A magnetic sensor device according to an embodiment of the disclosure includes a support body that supports the chip, a coil group including a plurality of coils configured to apply a magnetic field to the plurality of magnetoresistive elements, and a plurality of bridge circuits configured with the plurality of magnetoresistive elements. The support body includes a plurality of first power supply pads for the plurality of bridge circuits, and at least one second power supply pad for the coil group. The number of the at least one second power supply pad is less than the number of the plurality of first power supply pads.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device according to a first example embodiment of the disclosure.

FIG. 2 is a plan view showing the magnetic sensor device according to the first example embodiment of the disclosure.

FIG. 3 is a functional block diagram showing a configuration of the magnetic sensor device according to the first example embodiment of the disclosure.

FIG. 4 is a circuit diagram showing a circuit configuration of a first detection circuit in the first example embodiment of the disclosure.

FIG. 5 is a circuit diagram showing a circuit configuration of a second detection circuit in the first example embodiment of the disclosure.

FIG. 6 is a circuit diagram showing a circuit configuration of a third detection circuit in the first example embodiment of the disclosure.

FIG. 7 is a perspective view showing a part of one resistor section in the first example embodiment of the disclosure.

FIG. 8 is a perspective view showing a magnetoresistive element in the first example embodiment of the disclosure.

FIG. 9 is a circuit diagram showing a circuit configuration of a first coil group and a second coil group in the first example embodiment of the disclosure.

FIG. 10 is a plan view showing a part of a first chip in the first example embodiment of the disclosure.

FIG. 11 is a plan view showing a part of a second chip in the first example embodiment of the disclosure.

FIG. 12 is a sectional view showing a part of the first chip in the first example embodiment of the disclosure.

FIG. 13 is a sectional view showing a part of the first chip in the first example embodiment of the disclosure.

FIG. 14 is a sectional view showing a part of the first chip in the first example embodiment of the disclosure.

FIG. 15 is a plan view showing a part of the first chip in the first example embodiment of the disclosure.

FIG. 16 is a plan view showing a part of the second chip in the first example embodiment of the disclosure.

FIG. 17 is a sectional view showing a part of the second chip in the first example embodiment of the disclosure.

FIG. 18 is an enlarged plan view showing a configuration of a plurality of first electrode pads of the first chip, a plurality of second electrode pads of the second chip, and a plurality of third electrode pads of a support body in the first example embodiment of the disclosure.

FIG. 19 is a circuit diagram showing a circuit configuration of a first coil group and a second coil group of a magnetic sensor device in a comparative example.

FIG. 20 is a plan view showing a part of a second chip in a second example embodiment of the disclosure.

FIG. 21 is a plan view showing a magnetic sensor device according to a third example embodiment of the disclosure.

FIG. 22 is a plan view showing a magnetic sensor device according to a fourth example embodiment of the disclosure.

FIG. 23 is a circuit diagram showing a circuit configuration of a second detection circuit in the fourth example embodiment of the disclosure.

FIG. 24 is a plan view showing a part of a second chip in the fourth example embodiment of the disclosure.

FIG. 25 is a sectional view showing a modification example in which arrangement of a first coil is changed in FIG. 13.

FIG. 26 is a plan view showing a magnetic sensor device in a fifth example embodiment of the disclosure.

### DETAILED DESCRIPTION

An object of the disclosure is to provide a magnetic sensor device that can achieve reduction in size and suitability for an operation under an environmental magnetic field.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.

### First Example Embodiment

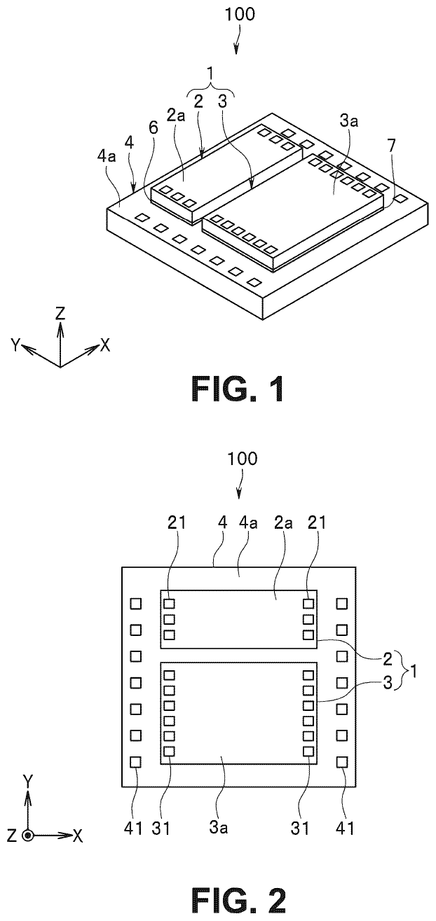

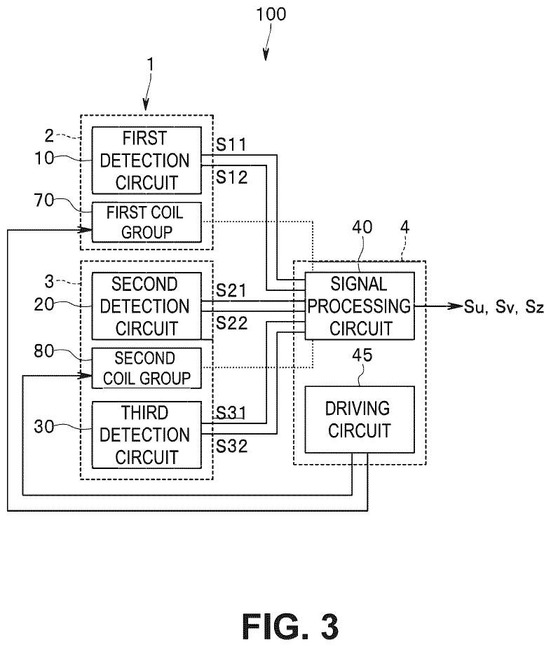

First, with reference to FIG. 1 to FIG. 3, a configuration of a magnetic sensor device according to a first example embodiment of the disclosure is described. FIG. 1 is a perspective view showing a magnetic sensor device 100. FIG. 2 is a plan view showing the magnetic sensor device 100. FIG. 3 is a functional block diagram showing a configuration of the magnetic sensor device 100. The magnetic sensor device 100 includes a magnetic sensor 1. The magnetic sensor 1 may be a geomagnetic sensor that detects the geomagnetic field, a magnetic sensor for a position detection device that detects a position of a magnet moving in a specific direction, a magnetic sensor for an angle sensor or a magnetic encoder that detects a rotating magnetic field, or a magnetic sensor for a current sensor that detects a magnetic field generated by a detected current.

The magnetic sensor device 100 includes a first chip 2, a second chip 3, and a support body 4 that supports the first chip 2 and the second chip 3. The magnetic sensor 1 includes the first chip 2 and the second chip 3. The first chip 2, the second chip 3, and the support body 4 each have a rectangular solid shape. The support body 4 has a reference plane 4a that is a top surface, a bottom surface located opposite to the reference plane 4a, and four side surfaces connecting the reference plane 4a and the bottom surface.

Here, a description is given of a reference coordinate system in the present example embodiment with reference to FIG. 1 and FIG. 2. The reference coordinate system is an orthogonal coordinate system that is set with reference to the magnetic sensor device 100 and defined by three axes. An X direction, a Y direction, and a Z direction are defined in the reference coordinate system. The X, Y, and Z directions are orthogonal to each other. In particular, in the present example embodiment, a direction that is perpendicular to the reference plane 4a of the support body 4 and directed from the bottom surface of the support body 4 to the reference plane 4a is referred to as the Z direction. The opposite directions to the X, Y, and Z directions are expressed as −X, −Y, and −Z directions, respectively. The three axes defining the reference coordinate system are an axis parallel to the X direction, an axis parallel to the Y direction, and an axis parallel to the Z direction.

As used herein, the term “above” refers to positions located ahead a certain reference position in the Z direction, and “below” refers to positions opposite from the “above” positions with respect to the certain reference position. For each component of the magnetic sensor device 100, the term “top surface” refers to a surface of the component located at the end thereof in the Z direction, and “bottom surface” refers to a surface of the component located at the end thereof in the −Z direction. The expression “when viewed in a specific direction (e.g., the Z direction)” means that an object is viewed from a position away in the specific direction or in one direction parallel to the specific direction.

The first chip 2 has a top surface 2a and a bottom surface that are located opposite to each other, and four side surfaces that connect the top surface 2a and the bottom surface. The second chip 3 has a top surface 3a and a bottom surface that are located opposite to each other, and four side surfaces that connect the top surface 3a and the bottom surface.

The first chip 2 is mounted on the reference plane 4a in a posture such that the bottom surface of the first chip 2 faces the reference plane 4a of the support body 4. The second chip 3 is mounted on the reference plane 4a in a posture such that the bottom surface of the second chip 3 faces the reference plane 4a of the support body 4. The first chip 2 and the second chip 3 are bonded to the support body 4 with, for example, adhesives 6 and 7, respectively.

The first chip 2 includes a plurality of first electrode pads 21 provided on the top surface 2a. In FIG. 2, the plurality of first electrode pads are denoted with the representative reference numeral 21. As described below, the plurality of first electrode pads 21 include six first electrode pads 21A, 21B, 21C, 21D, 21E, and 21F.

The second chip 3 includes a plurality of second electrode pads 31 provided on the top surface 3a. In FIG. 2, the plurality of second electrode pads are denoted with the representative reference numeral 31. As described below, the plurality of second electrode pads 31 include 12 second electrode pads 31A, 31B, 31C, 31D, 31E, 31F, 31G, 31H, 31I, 31J, 31K, and 31L.

The support body 4 includes a plurality of third electrode pads 41 provided on the reference plane 4a. In FIG. 2, the plurality of third electrode pads are denoted with the representative reference numeral 41. As described below, the plurality of third electrode pads 41 include 14 third electrode pads 41A, 41B, 41C, 41D, 41E, 41F, 41G, 41H, 41I, 41J, 41K, 41L, 41M, and 41N.

Although omitted in illustration, in the magnetic sensor device 100, two corresponding electrode pads among the plurality of first electrode pads 21, the plurality of second electrode pads 31, and the plurality of third electrode pads 41 are connected to each other by a conductor such as a bonding wire or a redistribution layer (RDL).

As shown in FIG. 3, the magnetic sensor 1 includes a first detection circuit 10, a second detection circuit 20, and a third detection circuit 30. The first chip 2 includes the first detection circuit 10. The second chip 3 includes the second detection circuit 20 and the third detection circuit 30. The magnetic sensor 1 is a component of the magnetic sensor device 100, and hence it can also be understood that the magnetic sensor device 100 includes the first to third detection circuits 10, 20, and 30.

The magnetic sensor device 100 further includes a signal processing circuit 40 and a driving circuit 45. The support body 4 may include the signal processing circuit 40 and the driving circuit 45. The first to third detection circuits 10, 20, and 30 and the signal processing circuit 40 are connected via the plurality of first electrode pads 21, the plurality of second electrode pads 31, the plurality of third electrode pads 41, and a plurality of conductors such as bonding wires or redistribution layers (RDL).

The first to third detection circuits 10, 20, and 30 each include a plurality of magnetic detection elements, and are configured to detect a target magnetic field and generate at least one detection signal. In particular, in the example embodiment, the plurality of magnetic detection elements are a plurality of magnetoresistive elements. The magnetoresistive elements are hereinafter referred to as MR elements.

The signal processing circuit 40 is configured to generate a first detection value, a second detection value, and a third detection value by processing the plurality of detection signals generated by the first to third detection circuits 10, 20, and 30. The first, second, and third detection values have a correspondence with components of the magnetic field in three respective different directions at a specific reference position. In particular, in the present example embodiment, the foregoing three different directions are two directions parallel to an XY plane and a direction parallel to the Z direction.

The signal processing circuit 40 and the driving circuit 45 may be configured with one processor, or may be configured with processors different from each other. For example, the processor may be configured with an application-specific integrated circuit (ASIC). The driving circuit 45 is described below in detail.

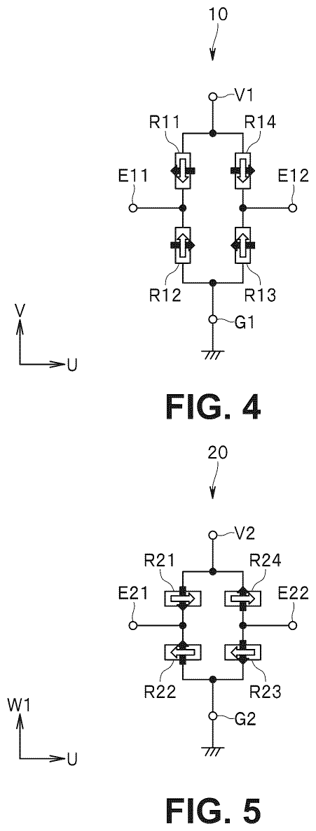

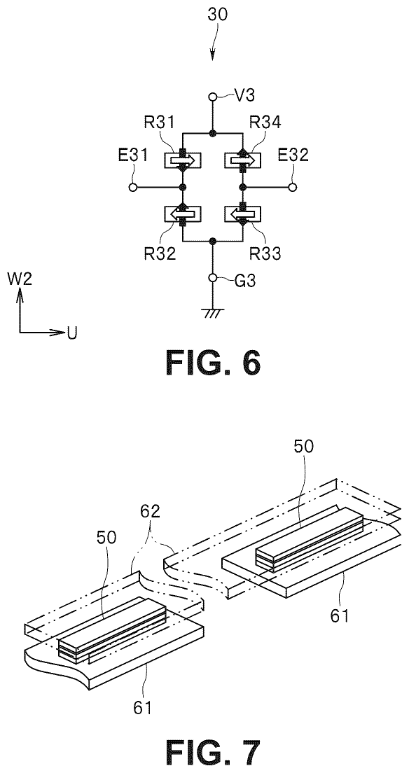

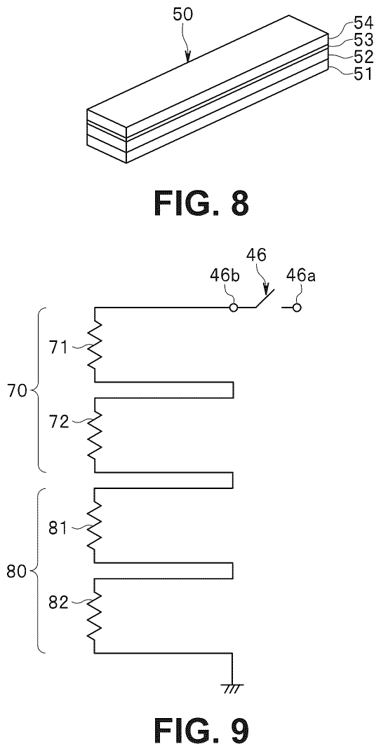

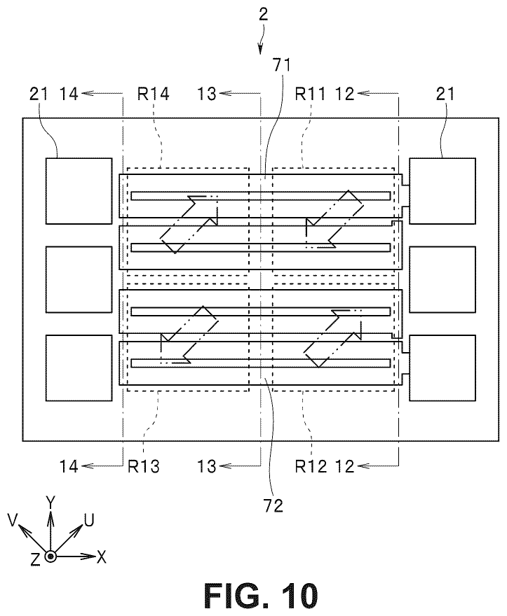

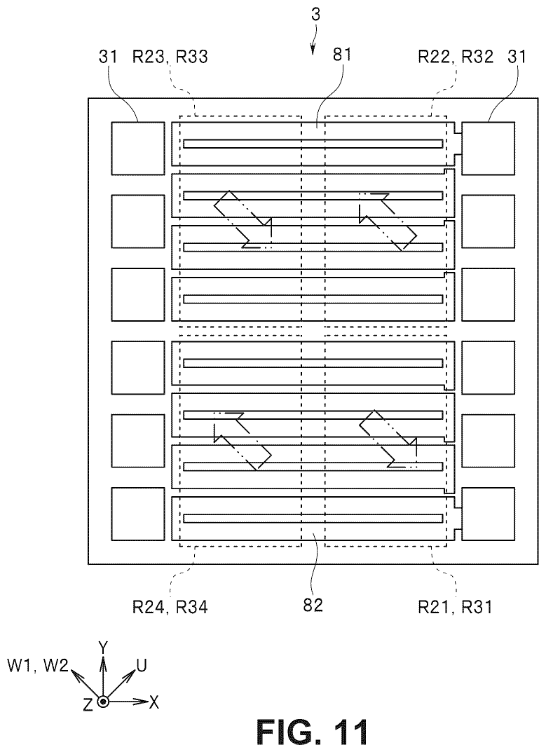

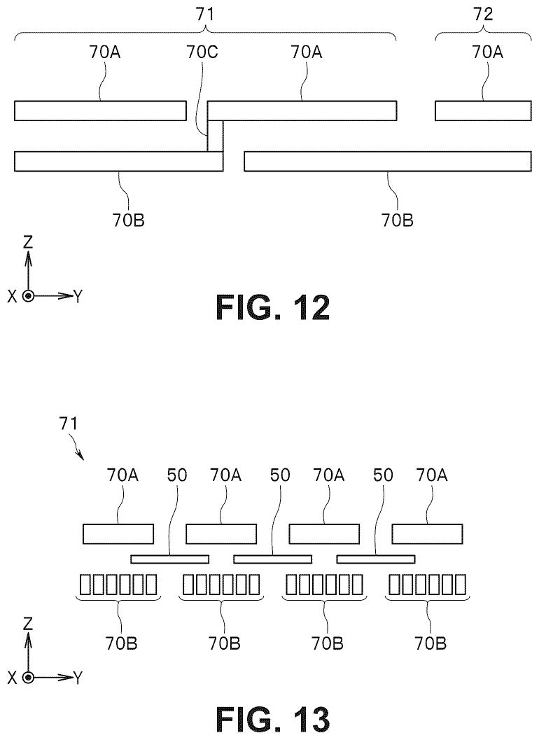

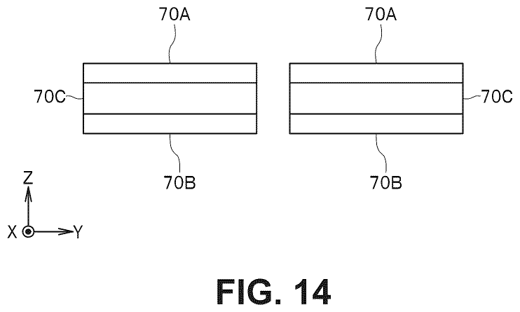

FIG. 4 is a circuit diagram showing a circuit configuration of the first detection circuit 10. FIG. 5 is a circuit diagram showing a circuit configuration of the second detection circuit 20. FIG. 6 is a circuit diagram showing a circuit configuration of the third detection circuit 30. FIG. 7 is a perspective view showing a part of one resistor section. FIG. 8 is a perspective view showing the magnetoresistive element. FIG. 9 is a circuit diagram showing a circuit configuration of a first coil group 70 and a second coil group 80. FIG. 10 is a plan view showing a part of the first chip 2. FIG. 11 is a plan view showing a part of the second chip 3. FIG. 12, FIG. 13, and FIG. 14 are sectional views showing a part of the first chip 2. FIG. 12 is a sectional view taken along the line 12-12 in FIG. 10, FIG. 13 is a sectional view taken along the line 13-13 in FIG. 10, and FIG. 14 is a sectional view taken along the line 14-14 in FIG. 10.

Here, as shown in FIG. 10, a U direction and a V direction are defined as follows. The U direction is a direction rotated from the X direction to the Y direction. The V direction is a direction rotated from the Y direction to the −X direction. More specifically, in the present example embodiment, the U direction is set to a direction rotated from the X direction to the Y direction by α, and the V direction is set to a direction rotated from the Y direction to the −X direction by α. Note that α is an angle greater than 0 degrees and smaller than 90 degrees. In one example, α is 45 degrees. A −U direction refers to a direction opposite to the U direction, and a −V direction refers to a direction opposite to the V direction.

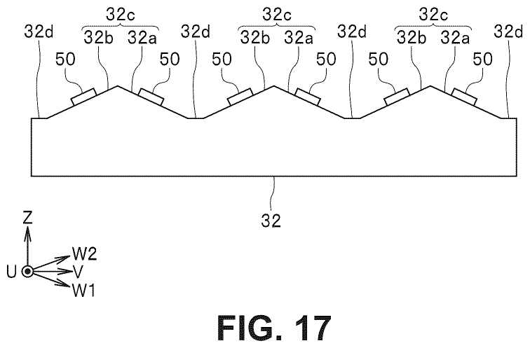

As shown in FIG. 5, FIG. 6, and FIG. 11 (further, FIG. 17 described below), a W1 direction and a W2 direction are defined as follows. The W1 direction is a direction rotated from the V direction to the −Z direction. The W2 direction is a direction rotated from the V direction to the Z direction. More specifically, in the present example embodiment, the W1 direction is set to a direction rotated from the V direction to the −Z direction by β, and the W2 direction is set to a direction rotated from the V direction to the Z direction by β. Note that β is an angle greater than 0 degrees and smaller than 90 degrees. A −W1 direction refers to a direction opposite to the W1 direction, and a −W2 direction refers to a direction opposite to the W2 direction. The W1 direction and W2 direction both are orthogonal to the U direction.

The first detection circuit 10 is configured to detect a component of the target magnetic field in a direction parallel to the U direction and generate at least one first detection signal which has a correspondence with the component. The second detection circuit 20 is configured to detect a component of the target magnetic field in a direction parallel to the W1 direction and generate at least one second detection signal which has a correspondence with the component. The third detection circuit 30 is configured to detect a component of the target magnetic field in a direction parallel to the W2 direction and generate at least one third detection signal which has a correspondence with the component.

As shown in FIG. 4, the first detection circuit 10 is a bridge circuit including a power supply port V1, a ground port G1, signal output ports E11 and E12, and resistor sections R11, R12, R13, and R14. The plurality of MR elements of the first detection circuit 10 constitute the resistor sections R11, R12, R13, and R14.

The resistor section R11 is provided between the power supply port V1 and the signal output port E11. The resistor section R12 is provided between the signal output port E11 and the ground port G1. The resistor section R13 is provided between the signal output port E12 and the ground port G1. The resistor section R14 is provided between the power supply port V1 and the signal output port E12.

As shown in FIG. 5, the second detection circuit 20 is a bridge circuit including a power supply port V2, a ground port G2, signal output ports E21 and E22, and resistor sections R21, R22, R23, and R24. The plurality of MR elements of the second detection circuit 20 constitute the resistor sections R21, R22, R23, and R24.

The resistor section R21 is provided between the power supply port V2 and the signal output port E21. The resistor section R22 is provided between the signal output port E21 and the ground port G2. The resistor section R23 is provided between the signal output port E22 and the ground port G2. The resistor section R24 is provided between the power supply port V2 and the signal output port E22.

As shown in FIG. 6, the third detection circuit 30 is a bridge circuit including a power supply port V3, a ground port G3, signal output ports E31 and E32, and resistor sections R31, R32, R33, and R34. The plurality of MR elements of the third detection circuit 30 constitute the resistor sections R31, R32, R33, and R34.

The resistor section R31 is provided between the power supply port V3 and the signal output port E31. The resistor section R32 is provided between the signal output port E31 and the ground port G3. The resistor section R33 is provided between the signal output port E32 and the ground port G3. The resistor section R34 is provided between the power supply port V3 and the signal output port E32.

The first detection circuit 10 generates a signal corresponding to the electric potential of the signal output port E11 as a first detection signal S11, and generates a signal corresponding to the electric potential of the signal output port E12 as a first detection signal S12. The second detection circuit 20 generates a signal corresponding to the electric potential of the signal output port E21 as a second detection signal S21, and generates a signal corresponding to the electric potential of the signal output port E22 as a second detection signal S22. The third detection circuit 30 generates a signal corresponding to the electric potential of the signal output port E31 as a third detection signal S31, and generates a signal corresponding to the electric potential of the signal output port E32 as a third detection signal S32.

The signal processing circuit 40 is configured to generate a first detection value Su based on the first detection signals S11 and S12 and generate a second detection value Sv and a third detection value Sz based on the second detection signals S21 and S22 and the third detection signals S31 and S32. The first detection value Su is a detection value corresponding to the component of the target magnetic field in the direction parallel to the U direction. The second detection value Sv is a detection value corresponding to the component of the target magnetic field in the direction parallel to the V direction. The third detection value Sz is a detection value corresponding to the component of the target magnetic field in the direction parallel to the Z direction.

A voltage or a current having a specific magnitude is applied to each of the power supply ports V1 to V3. Each of the ground ports G1 to G3 is connected to the ground.

FIG. 7 shows a part of any given resistor section of the resistor sections R11 to R14 of the first detection circuit 10, the resistor sections R21 to R24 of the second detection circuit 20 and the resistor sections R31 to R34 of the third detection circuit 30. FIG. 7 shows an example in which MR elements of a current perpendicular-to-plane (CPP)type are connected in series. Any given resistor section includes a plurality of lower electrodes 61, a plurality of MR elements 50, and a plurality of upper electrodes 62. The plurality of lower electrodes 61 are arranged on a support member, which is described below. As shown in FIG. 7, each of the lower electrodes 61 has a long slender shape. Two lower electrodes 61 adjacent in the longitudinal direction of the lower electrodes 61 have a gap therebetween. As shown in FIG. 7, the MR elements 50 are arranged respectively near both longitudinal ends on the top surface of the lower electrode 61.

FIG. 8 is a perspective view showing the MR element (magnetoresistive element) 50. As shown in FIG. 8, the MR element 50 includes an antiferromagnetic layer 51, a magnetization pinned layer 52, a gap layer 53, and a free layer 54 that are stacked in the stated order from the lower electrode 61 side. The antiferromagnetic layer 51 is electrically connected to the lower electrode 61. The antiferromagnetic layer 51 is formed of an antiferromagnetic material, and is in exchange coupling with the magnetization pinned layer 52 to thereby pin the magnetization direction of the magnetization pinned layer 52.

As shown in FIG. 7, the plurality of upper electrodes 62 are arranged over the plurality of MR elements 50. Each of the upper electrodes 62 has a long slender shape, and electrically connects the free layers 54 of the two adjacent MR elements 50 that are arranged on two lower electrodes 61 adjacent in the longitudinal direction of the lower electrodes 61. With this configuration, the given resistor section shown in FIG. 7 includes the plurality of MR elements 50 that are connected in series by the plurality of lower electrodes 61 and the plurality of upper electrodes 62.

Note that the magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In a case where the magnetization pinned layer 52 is the self-pinned layer, the antiferromagnetic layer 51 may be omitted.

The layers 51 to 54 of each of the MR elements 50 may be stacked in the reverse order to that shown in FIG. 8.

The given resistor section may include a plurality of pairs in which the plurality of MR elements 50 are connected in parallel. The plurality of pairs may be connected in series. The MR element 50 may be a current in-plane (CIP) MR element.

In FIG. 4 to FIG. 6, each of the resistor sections R11 to R14, R21 to R24, and R31 to R34 is schematically represented by one MR element 50. In FIG. 4 to FIG. 6, solid arrows represent the magnetization directions of the magnetization pinned layers 52 of the MR elements 50. Hollow arrows represent the magnetization directions of the free layers 54 of the MR elements 50 in a case where no target magnetic field is applied to the MR elements 50.

In the example shown in FIG. 4, the magnetization directions of the magnetization pinned layers 52 of the MR elements 50 in each of the resistor sections R11 and R13 are the −U direction. The magnetization directions of the magnetization pinned layers 52 of the MR elements 50 in each of the resistor sections R12 and R14 are the U direction. When the target magnetic field is not applied, the magnetization directions of the free layer 54 of the MR elements 50 in each of the resistor sections R11 and R14 are the −V direction. When the target magnetic field is not applied, the magnetization directions of the free layer 54 of the MR elements 50 in each of the resistor sections R12 and R13 are the V direction.

In the example shown in FIG. 5, the magnetization directions of the magnetization pinned layers 52 of the MR elements 50 in each of the resistor sections R21 and R23 are the −W1 direction. The magnetization directions of the magnetization pinned layers of the MR elements 50 in each of the resistor sections R22 and R24 are the W1 direction. When the target magnetic field is not applied, the magnetization directions of the free layer 54 of the MR elements 50 in each of the resistor sections R21 and R24 are the U direction. When the target magnetic field is not applied, the magnetization directions of the free layer 54 of the MR elements 50 in each of the resistor sections R22 and R23 are the −U direction.

In the example shown in FIG. 6, the magnetization directions of the magnetization pinned layers 52 of the MR elements 50 in each of the resistor sections R31 and R33 are the −W2 direction. The magnetization directions of the magnetization pinned layers of the MR elements 50 in each of the resistor sections R32 and R34 are the W2 direction. When the target magnetic field is not applied, the magnetization directions of the free layer 54 of the MR elements 50 in each of the resistor sections R31 and R34 are the U direction. When the target magnetic field is not applied, the magnetization directions of the free layer 54 of the MR elements 50 in each of the resistor sections R32 and R33 are the −U direction.

Hereinafter, the plurality of MR elements of the first detection circuit 10 may be referred to as a “plurality of first MR elements”, and the plurality of MR elements of the second detection circuit 20 and the third detection circuit 30 may be referred to as a “plurality of second MR elements”. The first to third detection circuits 10, 20, and 30 are components of the magnetic sensor 1, and hence it can also be understood that the magnetic sensor 1 includes “the plurality of first MR elements” and “the plurality of second MR elements”. The given MR element including “the plurality of first MR elements” and “the plurality of second MR elements” are continuously denoted with the reference numeral 50.

The magnetic sensor 1 includes a magnetic field generator configured to apply a magnetic field in a specific direction to the free layer 54 of each of the plurality of first MR elements 50 (the plurality of first MR elements and the plurality of second MR elements). In the example embodiment, the magnetic field generator includes the first coil group 70 including at least one first coil configured to apply a magnetic field in a specific direction with respect to the free layer 54 in each of the plurality of MR elements 50 (the plurality of first MR elements) of the first detection circuit 10, and the second coil group 80 including at least one second coil configured to apply a magnetic field in a specific direction with respect to the free layer 54 in each of the plurality of MR elements 50 (the plurality of second MR elements) of the second detection circuit 20 and the third detection circuit 30. The first coil group 70 and the second coil group 80 are formed of a conductive material such as Cu.

The first chip 2 includes the first coil group 70. In other words, the first chip 2 and the first coil group 70 may be integrated with each other. The second chip 3 may include the second coil group 80. In other words, the second chip 3 and the second coil group 80 may be integrated with each other. The support body 4 may include the driving circuit 45 configured to drive the first coil group 70 and the second coil group 80.

As shown in FIG. 9, the first coil group 70 includes two first coils 71 and 72. The second coil group 80 includes two second coils 81 and 82. The two first coils 71 and 72 and the two second coils 81 and 82 may be connected in series in the stated order. The driving circuit 45 includes a switch 46. The switch 46 includes an input port 46a and an output port 46b. The input port 46a is connected to a power source, which is omitted in illustration. The output port 46b is connected to the first coil 71. The second coil 82 is connected to the ground.

Here, with reference to FIG. 10, the arrangement of the resistor sections R11 to R14 in the first chip 2 is described. In FIG. 10, the region in which the resistor section R11 is arranged is denoted with the reference numeral R11, the region in which the resistor section R12 is arranged is denoted with the reference numeral R12, the region in which the resistor section R13 is arranged is denoted with the reference numeral R13, and the region in which the resistor section R14 is arranged is denoted with the reference numeral R14. In the example shown in FIG. 10, the resistor sections R11 and R12 are arrayed in the stated order in the −Y direction. The resistor sections R13 and R14 are arranged in front of the resistor sections R12 and R11, respectively, in the −X direction.

As shown in FIG. 10, the first coil 71 is configured to apply a magnetic field to the MR elements 50 (the plurality of first MR elements) corresponding to the resistor sections R11 and R14. The first coil 72 is configured to apply a magnetic field to the MR elements 50 (the plurality of first MR elements) corresponding to the resistor sections R12 and R13.

The first coil 71 includes a plurality of coil parts, specifically, a coil part configured to generate a magnetic field in a first direction that is applied to the MR elements 50 (the plurality of first MR elements) corresponding to the resistor section R11 and a coil part configured to generate a magnetic field in the first direction that is applied to the MR elements 50 (the plurality of first MR elements) corresponding to the resistor section R14. The first coil 72 includes a plurality of coil parts, specifically, a coil part configured to generate a magnetic field in a second direction that is applied to the MR elements 50 (the plurality of first MR elements) corresponding to the resistor section R13 and a coil part configured to generate a magnetic field in the second direction that is applied to the MR elements 50 (the plurality of first MR elements) corresponding to the resistor section R12.

Here, with reference to FIG. 11, the arrangement of the resistor sections R21 to R24 and R31 to R34 in the second chip 3 is described. In FIG. 11, the region in which the pair of the resistor sections R21 and R31 are arranged is denoted with the reference numeral R21, R31, the region in which the pair of the resistor sections R22 and R32 are arranged is denoted with the reference numeral R22, R32, the region in which the pair of the resistor sections R23 and R33 are arranged is denoted with the reference numeral R23, R33, and the region in which the pair of the resistor sections R24 and R34 are arranged is denoted with the reference numeral R24, R34. In the example shown in FIG. 11, the pair of the resistor sections R21 and R31 and the pair of the resistor sections R22 and R32 are arrayed in the stated order in the Y direction. The pair of the resistor sections R23 and R33 are arranged in front of the pair of the resistor sections R22 and R32 in the −X direction. The pair of the resistor sections R24 and R34 are arranged in front of the pair of the resistor sections R21 and R31 in the −X direction.

As shown in FIG. 11, the second coil 81 is configured to apply a magnetic field to the MR elements 50 (the plurality of second MR elements) corresponding to the resistor sections R22, R23, R32, and R33. The second coil 82 is configured to apply a magnetic field to the MR elements 50 (the plurality of second MR elements) corresponding to the resistor sections R21, R24, R31, and R34.

The second coil 81 includes a plurality of coil parts, specifically, a coil part configured to generate a magnetic field in the first direction that is applied to the MR elements 50 (the plurality of second MR elements) corresponding to the resistor sections R22 and R32 and a coil part configured to generate a magnetic field in the first direction that is applied to the MR elements 50 (the plurality of second MR elements) corresponding to the resistor sections R23 and R33. The second coil 82 includes a plurality of coil parts, specifically, a coil part configured to generate a magnetic field in the second direction that is applied to the MR elements 50 (the plurality of second MR elements) corresponding to the resistor sections R24 and R34 and a coil part configured to generate a magnetic field in the second direction that is applied to the MR elements 50 (the plurality of second MR elements) corresponding to the resistor sections R21 and R31.

With reference to FIG. 12 to FIG. 14, the configurations of the first coils 71 and 72 of the first coil group 70 are further described. Each of the first coils 71 and 72 includes a plurality of upper coil elements 70A, a plurality of lower coil elements 70B, and a plurality of connection portions 70C that connect the plurality of upper coil elements 70A and the plurality of lower coil elements 70B. The plurality of upper coil elements 70A are arrayed in a direction parallel to the Y direction. The plurality of lower coil elements 70B are arrayed in a direction parallel to the Y direction. Each of the plurality of upper coil elements 70A and the plurality of lower coil elements 70B includes at least one conductor layer extending in a direction parallel to the X direction. The plurality of connection portions 70C connect the plurality of upper coil elements 70A and the plurality of lower coil elements 70B so that the upper coil element 70A and the lower coil element 70B are connected in an alternating manner.

The plurality of MR elements 50 (the plurality of first MR elements) are arranged between the plurality of upper coil elements 70A and the plurality of lower coil elements 70B. The at least one conductor layer is arranged to overlap with at least one of the MR elements 50 (the plurality of first MR elements) as viewed in the Z direction.

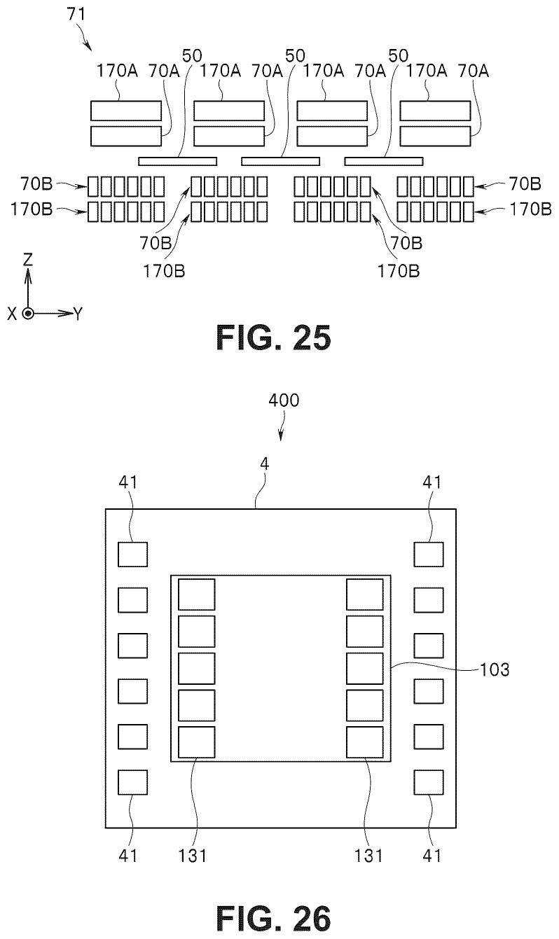

In the example shown in FIG. 10 and FIG. 12 to FIG. 14, each of the first coils 71 and 72 includes two upper coil elements 70A, two lower coil elements 70B, and three connection portions 70C. One of the two lower coil elements 70B of the first coil 71 and one of the two lower coil elements 70B of the first coil 72 are connected to each other. Each of the two upper coil elements 70A includes two upper conductor layers that extend in a direction parallel to the X direction and are connected in parallel. Each of the two lower coil elements 70B includes 12 lower conductor layers that extend in a direction parallel to the X direction and are connected to each other in parallel. Each of the two upper conductor layers are arranged to overlap with the six lower conductor layers as viewed in the Z direction. Note that the numbers of the lower conductor layers and the upper conductor layers are not limited to the numbers described above, and may be freely selected. The numbers of the lower conductor layers and the upper conductor layers in the Z direction are also freely selected. The lower conductor layers (the upper conductor layers) may extend in a direction parallel to the Z direction, and may be connected in parallel. FIG. 25 is a sectional view showing a modification example in which arrangement of the first coil 71 is changed in FIG. 13. In FIG. 25, the first coil 71 includes a set in which the upper coil element 70A (first upper conductor layer) and an upper coil element 170A (second upper conductor layer) are arrayed in a direction parallel to the Z direction. The first coil 71 includes a set in which the lower coil element 70B (first lower conductor layer) and a lower coil element 170B (second lower conductor layer) are arrayed in a direction parallel to the Z direction.

The first coil 71 and the first coil 72 are configured to apply magnetic fields in directions opposite to each other with respect to the MR elements 50 (the plurality of first MR elements). The first coil 71 applies a magnetic field in the −Y direction or the Y direction to the MR elements 50 (the plurality of first MR elements) corresponding to the resistor sections R11 and R14. The first coil 72 applies a magnetic field in the Y direction or the −Y direction to the MR elements 50 (the plurality of first MR elements) corresponding to the resistor sections R12 and R13.

Although omitted in illustration, the second coils 81 and 82 of the second coil group 80 also have similar structures as the first coils 71 and 72 of the first coil group 70. In other words, each of the second coils 81 and 82 includes the plurality of upper coil elements, the plurality of lower coil elements, and the plurality of connection portions that connect the plurality of upper coil elements and the plurality of lower coil elements. The plurality of upper coil elements are arrayed in a direction parallel to the Y direction. The plurality of lower coil elements are arrayed in a direction parallel to the Y direction. Each of the plurality of upper coil elements and the plurality of lower coil elements includes at least one conductor layer extending in a direction parallel to the X direction. The plurality of connection portions connect the plurality of upper coil elements and the plurality of lower coil elements so that the upper coil elements and the lower coil elements are connected in an alternating manner.

The plurality of MR elements 50 (the plurality of second MR elements) are arranged between the plurality of upper coil elements and the plurality of lower coil elements. The at least one conductor layer is arranged to overlap with at least one of the MR elements 50 (the plurality of second MR elements) as viewed in the Z direction.

In the example shown in FIG. 11 to FIG. 14, each of the second coils 81 and 82 includes four upper coil elements, four lower coil elements, and seven connection portions. One of the four lower coil elements of the second coil 81 and one of the four lower coil elements of the second coil 82 are connected to each other. Each of the four upper coil elements includes two upper conductor layers that extend in a direction parallel to the X direction and are connected in parallel. Each of the four lower coil elements includes 12 lower conductor layers that extend in a direction parallel to the X direction and are connected to each other in parallel. Each of the two upper conductor layers are arranged to overlap with the six lower conductor layers as viewed in the Z direction. Note that the numbers of the lower conductor layers and the upper conductor layers are not limited to the numbers described above, and may be freely selected. The numbers of the lower conductor layers and the upper conductor layers in the Z direction are also freely selected. The lower conductor layers (the upper conductor layers) may extend in a direction parallel to the Z direction, and may be connected in parallel. For example, with reference to FIG. 25 described above, the second coil 81 may include a set in which the first upper coil element (first upper conductor layer) and a second upper coil element (second upper conductor layer) are arrayed in a direction parallel to the Z direction. The second coil 81 may include a set in which the second lower coil element (first upper conductor layer) and a second lower coil element (second lower conductor layer) are arrayed in a direction parallel to the Z direction.

The second coil 81 and the second coil 82 are configured to apply magnetic fields in directions opposite to each other with respect to the MR elements 50 (the plurality of second MR elements). The second coil 81 applies a magnetic field in the −Y direction or the Y direction to the MR elements 50 (the plurality of second MR elements) corresponding to the resistor sections R22, R23, R32, and R33. The second coil 82 applies a magnetic field in the Y direction or the −Y direction to the MR elements 50 (the plurality of second MR elements) corresponding to the resistor sections R21, R24, R31, and R34.

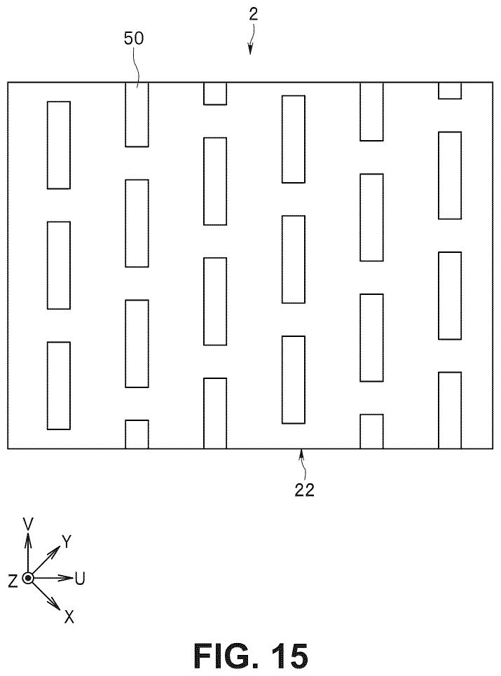

FIG. 15 is a plan view showing a part of the first chip 2. The first chip 2 includes a support member 22 formed of an insulating material. On the upper surface of the support member 22, the plurality of MR elements 50 (the plurality of first MR elements), the plurality of lower electrodes 61 (omitted in illustration), and the plurality of upper electrodes 62 (omitted in illustration) are arranged. The MR elements 50 (the plurality of first MR elements) provided to the first detection circuit 10 are arranged so that two or more MR elements are arrayed both in the U direction and in the V direction. The plurality of MR elements 50 (the plurality of first MR elements) are connected in series by the plurality of lower electrodes 61 and the plurality of upper electrodes 62 (see FIG. 7). Note that the two given MR elements 50 (the plurality of first MR elements) adjacent in the U direction may be shifted in a direction parallel to the V direction as viewed in the Z direction.

The plurality of upper coil elements 70A of each of the first coils 71 and 72 are arranged on the support member 22, specifically, on the plurality of MR elements 50 (the plurality of first MR elements), the plurality of lower electrodes 61, and the plurality of upper electrodes 62. The plurality of lower coil elements 70B of each of the first coils 71 and 72 are arranged between a substrate, which is omitted in illustration, and the support member 22. The plurality of connection portions 70C of each of the first coils 71 and 72 are provided to pass through the support member 22.

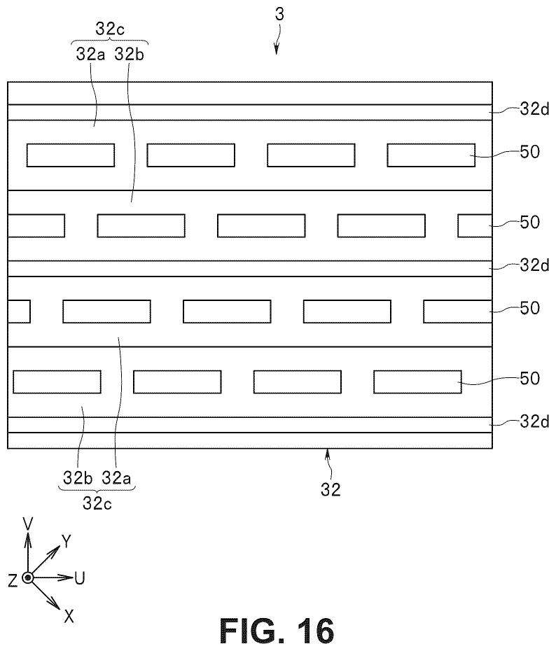

FIG. 16 is a plan view showing a part of the second chip 3. FIG. 17 is a sectional view showing a part of the second chip 3. The second chip 3 includes a support member 32 formed of an insulating material. On the upper surface of the support member 32, the plurality of MR elements 50 (the plurality of second MR elements), the plurality of lower electrodes 61 (omitted in illustration), and the plurality of upper electrodes 62 (omitted in illustration) are arranged. The support member 32 includes a plurality of projection surfaces 32c that are arrayed at a predetermined interval in the V direction and extend in the U direction. The projection surface 32c includes an inclination surface 32a increased in height in the Z direction as proceeding in the −V direction and an inclination surface 32b increased in height in the Z direction as proceeding in the V direction, and has a shape in which top portions of the inclination surface 32a and the inclination surface 32b are connected to each other. The inclination surface 32a and the inclination surface 32b may be a plane or curved surface. Between the projection surfaces 32c adjacent in the V direction (between the inclination surface 32a and the inclination surface 32b), a flat portion 32d including a plurality of parts each extending in the U direction and being parallel to the XY plane is provided.

Note that the projection surface 32 c may be a protruding surface formed on the upper surface of the support member 32. Alternatively, the projection surface 32c may be a surface of a groove portion formed in the upper surface of the support member 32. In such a case, the flat portion 32d serves as a bottom surface of the groove portion.

The plurality of MR elements 50 (the plurality of second MR elements) provided to the second detection circuit 20 are arranged on the inclination surface 32a so that two or more MR elements are arrayed in the U direction. The plurality of MR elements 50 (the plurality of second MR elements) provided to the third detection circuit 30 are arranged on the inclination surface 32b so that two or more MR elements are arrayed in the U direction. One MR element 50 that is arranged on the inclination surface 32a and another MR element 50 that is adjacent to the one MR element 50 and is arranged on the inclination surface 32b may be shifted in a direction parallel to the U direction as viewed in the Z direction.

The plurality of upper coil elements of each of the second coils 81 and 82 are arranged on the support member 32, specifically, on the plurality of MR elements 50 (the plurality of second MR elements), the plurality of lower electrodes 61, and the plurality of upper electrodes 62. The plurality of lower coil elements of each of the second coils 81 and 82 are arranged between a substrate, which is omitted in illustration, and the support member 32. The plurality of connection portions of each of the second coils 81 and 82 are provided to pass through the support member 32.

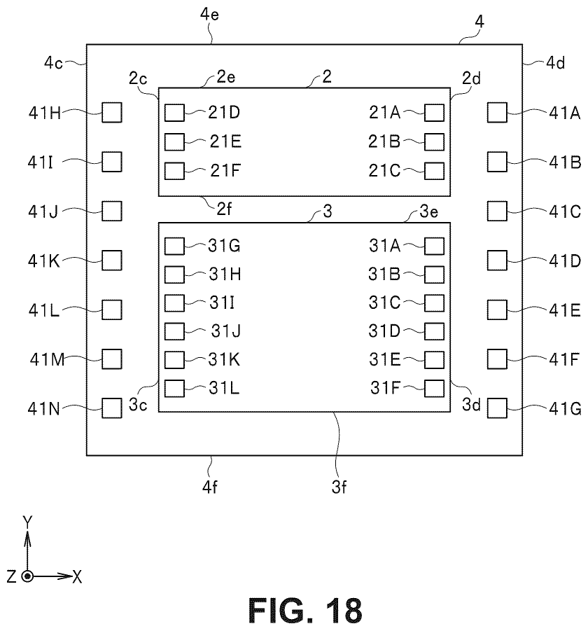

FIG. 18 is an enlarged plan view showing configurations of the plurality of first electrode pads 21 of the first chip 2, the plurality of second electrode pads 31 of the second chip 3, and the plurality of third electrode pads 41 of the support body 4.

The first chip 2 includes two end portions 2c and 2d located at both ends in the direction parallel to the X direction, and two end portions 2e and 2f located at both ends in the direction parallel to the Y direction. The end portion 2c is located at an end of the first chip 2 in the −X direction. The end portion 2d is located at an end of the first chip 2 in the X direction. The end portion 2e is located at an end of the first chip 2 in the Y direction. The end portion 2f is located at an end of the first chip 2 in the −Y direction. The four end portions 2c to 2f are also four side surfaces connecting the top surface 2a and the bottom surface of the first chip 2.

The magnetic sensor 1 includes the plurality of first electrode pads 21 as a plurality of sensor terminals provided to the first chip 2. The plurality of first electrode pads 21 of the first chip 2 includes the six first electrode pads 21A, 21B, 21C, 21D, 21E, and 21F. The three first electrode pads 21A to 21C and the three first electrode pads 21D to 21F are arranged to be separated in the X direction and arrayed in the Y direction.

The first electrode pads 21D and 21E are a plurality of (two) signal terminals. The first electrode pads 21A, 21B, 21C, and 21F are a plurality of (four) power supply terminals. The first electrode pads 21D to 21F are arranged on the end portion 2c side of the first chip 2. The first electrode pads 21D to 21F are arrayed in the stated order in the −Y direction along the end portion 2c of the first chip 2.

The first electrode pads 21A to 21C are arranged on the end portion 2d side of the first chip 2. The first electrode pads 21A to 21C are arrayed in the stated order in the −Y direction along the end portion 2d of the first chip 2. In the first chip 2, the number of terminals arranged on the end portion 2c side of the first chip 2 and the number of terminals arranged on the end portion 2d side of the first chip 2 are equal (three on each side).

The second chip 3 includes two end portions 3c and 3d located at both ends in the direction parallel to the X direction, and two end portions 3e and 3f located at both ends in the direction parallel to the Y direction. The end portion 3c is located at an end of the second chip 3 in the −X direction. The end portion 3d is located at an end of the second chip 3 in the X direction. The end portion 3e is located at an end of the second chip 3 in the Y direction. The end portion 3f is located at an end of the second chip 3 in the −Y direction. The four end portions 3c to 3f are also four side surfaces connecting the top surface 3a and the bottom surface of the second chip 3.

The magnetic sensor 1 includes the plurality of second electrode pads 31 as a plurality of sensor terminals provided to the second chip 3. The plurality of second electrode pads 31 of the second chip 3 includes the 12 second electrode pads 31A, 31B, 31C, 31D, 31E, 31F, 31G, 31H, 31I, 31J, 31K, and 31L. The six second electrode pads 31A to 31F and the six second electrode pads 31G to 31L are arranged to be separated in the X direction and arrayed in the Y direction.

The second electrode pads 31I, 31J, 31K, and 31L are a plurality of (four) signal terminals. The second electrode pads 31A, 31B, 31C, 31D, 31E, 31G, and 31H are a plurality of (seven) power supply terminals. The second electrode pad 31F is an electrode pad (a dummy pad) that corresponds to neither a signal terminal nor a power supply terminal. The second electrode pads 31G to 31L are arranged in the end portion 3c side of the second chip 3. The second electrode pads 31G to 31L are arrayed in the stated order in the −Y direction along the end portion 3c of the second chip 3.

The second electrode pads 31A to 31F are arranged on the end portion 3d side of the second chip 3. The second electrode pads 31A to 31F are arrayed in the stated order in the −Y direction along the end portion 3d of the second chip 3. In the second chip 3, the number of terminals arranged on the end portion 3c side of the second chip 3 and the number of terminals arranged on the end portion 3d side of the second chip 3 are equal (six on each side).

The first chip 2 and the second chip 3 are arranged in the stated order along the Y direction. The first chip 2 and the second chip 3 are arranged so that the first electrode pad 21C of the first chip 2 and the second electrode pad 31A of the second chip 3 are adjacent and the first electrode pad 21F of the first chip 2 and the second electrode pad 31G of the second chip 3 are adjacent.

The number of the first electrode pads 21 provided to the first chip 2 is six. The number of the second electrode pads 31 provide to the second chip 3 is 12, which is greater than the number of the first electrode pads 21 provided to the first chip 2.

The support body 4 includes two end portions 4c and 4d located at both ends in the direction parallel to the X direction, and two end portions 4e and 4f located at both ends in the direction parallel to the Y direction. The end portion 4c is located at an end of the support body 4 in the −X direction. The end portion 4d is located at an end of the support body 4 in the X direction. The end portion 4e is located at an end of the support body 4 in the Y direction. The end portion 4f is located at an end of the support body 4 in the −Y direction. The four end portions 4c to 4f are also four side surfaces connecting the reference plane 4a and the bottom surface of the support body 4.

The signal processing circuit 40 includes the plurality of third electrode pads 41 as a plurality of circuit terminals provided to the support body 4. The plurality of third electrode pads 41 of the support body 4 includes 14 the third electrode pads 41A, 41B, 41C, 41D, 41E, 41F, 41G, 41H, 41I, 41J, 41K, 41L, 41M, and 41N. The seven third electrode pads 41A to 41G and the third electrode pads 41H to 41N are arranged to be separated in the X direction and arrayed in the Y direction.

The third electrode pads 41H, 41I, 41K, 41L, 41M, and 41N are a plurality of (six) signal terminals. The third electrode pads 41A, 41B, 41C, 41D, 41E, 41F, and 41J are a plurality of (seven) power supply terminals. The third electrode pads 41G is an electrode pad (a dummy pad) that corresponds to neither a signal terminal nor a power supply terminal. The third electrode pads 41H to 41N are arranged on the end portion 4c side of the support body 4. The third electrode pads 41H to 41N are arrayed in the stated order in the −Y direction along the end portion 4c of the support body 4.

The third electrode pads 41A to 41G are arranged on the end portion 4d side of the support body 4. The third electrode pads 41A to 41G are arrayed in the stated order in the −Y direction along the end portion 4d of the support body 4.

The first chip 2 and the second chip 3 are arranged between the third electrode pads 41A to 41G and the third electrode pads 41H to 41N.

Next, connection relationships between the plurality of electrode pads are described. For example, two given electrode pads of the plurality of electrode pads may be connected by a conductor such as a bonding wire or a redistribution layer (RDL). In FIG. 18, the conductor is omitted.

The first electrode pads 21A and 21B being power supply terminals of the first chip 2 are connected to the third electrode pads 41A and 41B being power supply terminals of the support body 4, respectively. The first electrode pads 21D and 21E being signal terminals of the first chip 2 are connected to the third electrode pads 41H and 41I being signal terminals of the support body 4, respectively. The first electrode pads 21C and 21F being power supply terminals of the first chip 2 are connected to the second electrode pads 31A and 31G being power supply terminals of the second chip 3, respectively.

The second electrode pads 31B, 31C, 31D, and 31E being power supply terminals of the second chip 3 are connected to the third electrode pads 41C, 41D, 41E, and 41F being power supply terminals of the support body 4, respectively. The second electrode pad 31H being a power supply terminal of the second chip 3 is connected to the third electrode pads 41J being a power supply terminal of the support body 4. The second electrode pads 31I, 31J, 31K, and 31L being signal terminals of the second chip 3 are connected to the third electrode pads 41K, 41L, 41M, and 41N being signal terminals of the support body 4, respectively.

The second electrode pads 31F of the second chip 3 may be connected or may not be connected to the third electrode pads 41G of the support body 4.

Next, relationships between the plurality of terminals and the circuit components shown in FIG. 3 to FIG. 6 are described. The first electrode pads 21D and 21E being signal terminals the first electrode pads 21B and 21F being power supply terminals that are provided to the first chip 2 are electrically connected to the first detection circuit 10 shown in FIG. 4. The first electrode pads 21D and 21E are electrically connected to the signal output ports E11 and E12, respectively. The first electrode pad 21B is electrically connected to the power supply port V1. The first electrode pad 21F is electrically connected to the ground port G1. The first electrode pads 21A and 21C provided to the first chip 2 are connected to the first coil group 70 shown in FIG. 3, and are used as terminals for the coils.

The second electrode pads 31I to 31L being signal terminals and the second electrode pads 31D, 31E, 31G, and 31H of being power supply terminals that are provided to the second chip 3 are electrically connected to the second detection circuit 20 shown in FIG. 5 and the third detection circuit 30 shown in FIG. 6. The second electrode pads 31I to 31L are electrically connected to the signal output ports E21, E22, E31, and E32, respectively. The second electrode pads 31D and 31E are electrically connected to the power supply ports V2 and V3, respectively. The second electrode pads 31G and 31H are each electrically connected to both the ground ports G2 and G3. The second electrode pads 31A to 31C provided to the second chip 3 are connected to the second coil group 80 shown in FIG. 3, and are used as terminals for the coils.

The first electrode pad 21F and the second electrode pads 31G and 31H are electrically connected to the third electrode pad 41J of the support body 4. The first electrode pad 21F, the second electrode pads 31G and 31H, and the third electrode pad 41J are connected to the ground.

Herein, the third electrode pads 41B of the support body 4 serves as a power supply pad (first power supply pad) for the bridge circuit for driving the first detection circuit 10 (applying a voltage or a current to the power supply port V1 in FIG. 4). The third electrode pads 41C of the support body 4 serves as a power supply pad (second power supply pad) for the bridge circuit for driving the second detection circuit 20 (applying a voltage or a current to the power supply port V2 in FIG. 5). The third electrode pads 41D of the support body 4 serves as a power supply pad (third power supply pad) for the bridge circuit for driving the third detection circuit 30 (applying a voltage or a current to the power supply port V3 in FIG. 6).

One of the third electrode pads 41A and 41E of the support body 4 serves as a power supply pad (fourth power supply pad) for driving the coils (the first coil group 70 and the second coil group 80) that apply a magnetic field to the magnetoresistive elements (the MR elements 50). The other of the third electrode pads 41A and 41E is a ground pad connected to the ground. In the following description, unless otherwise described, the third electrode pad 41A is a power supply pad (fourth power supply pad), and the third electrode pad 41E is a ground pad.

A detailed description is given with reference to FIG. 9. The first coils 71 and 72 of the first coil group 70 are driven by a driving current supplied from the first electrode pad 21A of the first chip 2 to the first electrode pad 21C via the third electrode pad 41A of the support body 4. Then, the second coils 81 and 82 of the second coil group 80 are driven by a driving current supplied from the second electrode pad 31A of the second chip 3 to the second electrode pad 31D.

The support body 4 may include, as at least one power supply pad, four power supply pads including the first, second, and third power supply pads 41B, 41C, and 41D for driving the detection circuits, and the fourth power supply pad 41A for driving the coils.

The second chip 3 may include the second electrode pads 31D as an electrode pad connected to the ground pad (the third electrode pad 41E of the support body 4). In contrast, the first chip 2 may not include an electrode pad connected to the ground pad (the third electrode pad 41E of the support body 4).

The magnetic sensor device 100 of the example embodiment includes the first chip 2 including the plurality of first MR elements (the plurality of MR elements 50 of the first detection circuit 10). The magnetic sensor device 100 includes the second chip 3 including the plurality of second MR elements (the plurality of MR elements 50 of the second detection circuit 20 and the third detection circuit 30). The magnetic sensor device 100 includes the support body 4 that supports the first chip 2 and the second chip 3. The magnetic sensor device 100 includes the first coil group 70 including the at least one first coil configured to apply a magnetic field to the plurality of first MR elements. The magnetic sensor device 100 includes the second coil group 80 including the at least one second coil configured to apply a magnetic field to the plurality of second MR elements.

The support body 4 includes the at least one power supply pad (the first, second, third, and fourth power supply pads 41B, 41C, 41D, and 41A) and the ground pad 41E.

The first coil group 70 includes the first end (the part corresponding to the first electrode pad 21A, the first coil 71) that is connected to the at least one power supply pad (for example, the fourth power supply pad 41A for driving the coils) and the second end (the part corresponding to the first electrode pad 21C, the first coil 72) located at an end opposite to the first end.

The second coil group 80 includes the third end (the part corresponding to the second electrode pad 31A, the second coil 81) connected to the second end (the part corresponding to the first electrode pad 21C, the first coil 72) of the first coil group 70, and the fourth end (the part corresponding to the second electrode pad 31D, the second coil 82) located at an end opposite to the third end and connected to the ground pad 41E.

Further, the number of the at least one power supply pad is equal to or less than the total number of the at least one first coil and the at least one second coil. More specifically, the at least one power supply pad is four power supply pads including the first, second, and third power supply pads 41B, 41C, and 41D for driving the detection circuits, and the fourth power supply pad 41A for driving the coils. Meanwhile, the at least one first coil and the at least one second coil are four coils, specifically, the first coils 71 and 72 of the first coil group 70 and the second coils 81 and 82 of the second coil group 80.

With this, reduction in size of the magnetic sensor device 100 and suitability for an operation under an environmental magnetic field can be achieved. Examples of operations under an environmental magnetic field include a set/reset operation and a self-test operation using a coil. The set/reset operation is an operation that enables more accurate detection of a target magnetic field by aligning magnetization of the free layer 54 in each of the MR elements in a specific direction before performing a detection operation of the target magnetic field. The self-test operation is an operation for confirming that the magnetic sensor device 100 operates normally or for checking sensitivity and offset before performing the detection operation of the target magnetic field.

In the magnetic sensor device 100 of the example embodiment, the first coils 71 and 72 of the first coil group 70 and the second coils 81 and 82 of the second coil group 80 are connected to reduce the numbers of the electrode pads and the switches. With this, the magnetic sensor device 100 can be reduced in size. For example, when the driving circuit 45 is configured with an application-specific integrated circuit (ASIC), a voltage that can be generally applied by the ASIC is fixed, and hence it is necessary to reduce resistance of the entire circuit. In the example embodiment, as described above, by setting the number of the at least one power supply pad to be equal to or less than the total number of the at least one first coil and the at least one second coil, switches can be reduced and the size of the ASIC can be decreased, and resistance inside the ASIC can be reduced. In particular, by reducing the lengths of the connected coils (the first coils 71 and 72 of the first coil group 70 and the second coils 81 and 82 of the second coil group 80) to reduce resistances of the respective coils, current values flowing through the respective coils can be increased. Further, by increasing a magnetic field that can be applied from the coil to the MR element 50, suitable set/reset operations and self-test operations can be achieved even under a strong environmental magnetic field.

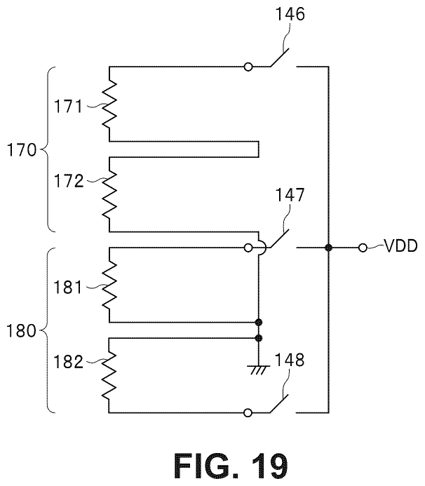

Herein, the effects of the magnetic sensor device 100 of the example embodiment are described while comparing with a magnetic sensor device in a comparative example. FIG. 19 is a circuit diagram (a circuit configuration corresponding to FIG. 9) showing a circuit configuration of a first coil group and a second coil group of the magnetic sensor device in the comparative example. The magnetic sensor device in the comparative example includes a first coil group 170 and a second coil group 180. FIG. 19 shows the first coil group 170 including two first coils 171 and 172 and the second coil group 180 including two second coils 181 and 182.

In the comparative example shown in FIG. 19, a switch 146 for driving the first coil group 170 (the two first coils 171 and 172) and two switches 147 and 148 for driving the two second coils 181 and 182 of the second coil group 180, respectively, are provided, and hence the increase in size of the magnetic sensor device cannot be avoided. In the comparative example, as the magnetic sensor device is increased in size, the lengths of the respective coils are increased, and resistances of the respective coils are increased. Therefore, current values that can flow through the respective coils cannot be increased, and hence, a magnetic field that can be applied from the respective coils to the MR elements cannot be increased. Thus, in the comparative example, it is difficult to perform suitable set/reset operations and self-test operations under a strong environmental magnetic field.

In contrast, according to the example embodiment shown in FIG. 9, the first coil group 70 (the two first coils 71 and 72) and the second coil group 80 (the two second coils 81 and 82) that are connected in series can be driven and controlled by the one switch 46 of the driving circuit 45. With this, according to the example embodiment, as described above, the size of the magnetic sensor device 100 can be reduced, and suitable set/reset operations and self-test operations can be achieved even under a strong environmental magnetic field.

### Second Example Embodiment

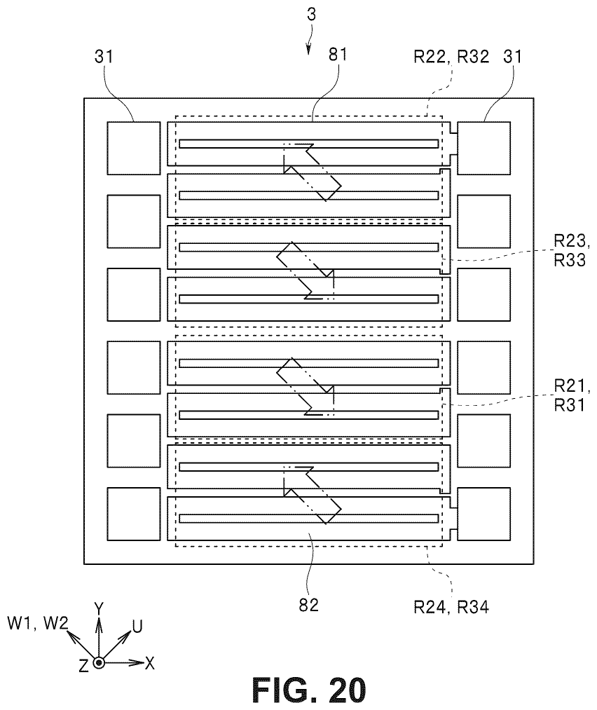

Next, with reference to FIG. 20, a second example embodiment of the disclosure is described. FIG. 20 is a plan view showing a part of the second chip 3 of the example embodiment. The plan view of FIG. 20 corresponds to the plan view of FIG. 11 in the first example embodiment.

Similarly to the first example embodiment, the second coil 81 of the second coil group 80 is configured to apply a magnetic field to the MR elements 50 (the plurality of second MR elements) corresponding to the resistor sections R22, R23, R32, and R33. The second coil 82 of the second coil group 80 is configured to apply a magnetic field to the MR elements 50 (the plurality of second MR elements) corresponding to the resistor sections R21, R24, R31, and R34.

In the example embodiment, the arrangement of the resistor sections R21 to R24 and R31 to R34 in the second chip 3 is different from the example shown in FIG. 11 in the first example embodiment. In the example shown in FIG. 20, the resistor sections R21 to R24 and R31 to R34 are arranged so that the pair of the resistor sections R22 and R32, the pair of the resistor sections R23 and R33, the pair of the resistor sections R21 and R31, and the pair of the resistor sections R24 and R34 are arrayed in the stated order in the −Y direction.

In the example shown in FIG. 20, the coil part of the second coil 81 configured to generate a magnetic field in the first direction that is applied to the MR elements 50 (the plurality of second MR elements) corresponding to the resistor sections R22 and R32, the coil part of the second coil 81 configured to generate a magnetic field in the first direction that is applied to the MR elements 50 (the plurality of second MR elements) corresponding to the resistor sections R23 and R33, the coil part of the second coil 82 configured to generate a magnetic field in the second direction that is applied to the MR elements 50 (the plurality of second MR elements) corresponding to the resistor sections R21 and R31, and the coil part of the second coil 82 configured to generate a magnetic field in the second direction that is applied to the MR elements 50 (the plurality of second MR elements) corresponding to the resistor sections R24 and R34 are arrayed in the stated order in the Y direction.

The configuration, operations, and effects of the example embodiment are otherwise the same as those of the first example embodiment.

### Third Example Embodiment

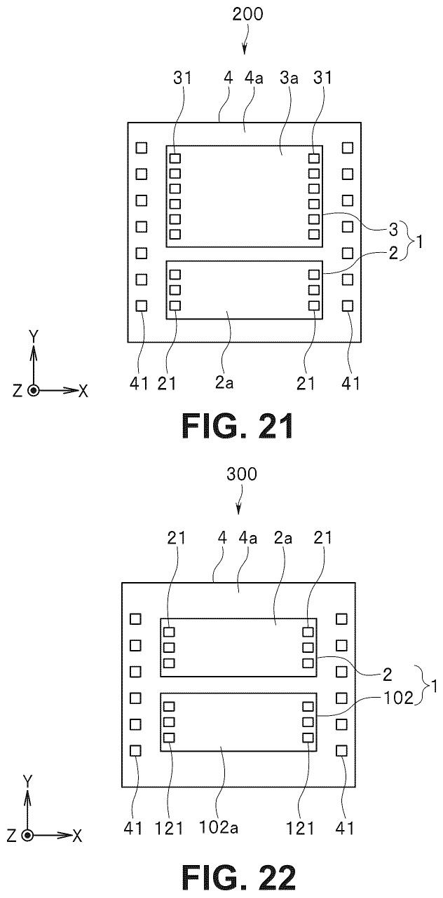

Next, with reference to FIG. 21, a third example embodiment of the disclosure is described. FIG. 21 is a plan view showing a magnetic sensor device 200 according to the example embodiment. The plan view of FIG. 21 corresponds to the plan view of FIG. 2 in the first example embodiment.

In the example embodiment, the positional relationship between the first chip 2 and the second chip 3 is opposite to that in the example shown in FIG. 2 in the first example embodiment. Accordingly, in the example embodiment, the first end of the first coil group 70 (the part corresponding to the first electrode pad 21A (see FIG. 18), the first coil 71 (see FIG. 9 and FIG. 10)) is connected to the ground pad (the third electrode pads 41E of the support body 4 (see FIG. 18)). The fourth end of the second coil group 80 (the part corresponding to the second electrode pads 31D (see FIG. 18), the second coil 82 (see FIG. 9 and FIG. 11)) is connected to the power supply pad for driving the coils (for example, the fourth power supply pad 41a of the support body 4 (see FIG. 18)).

Note that the function of each of the plurality of third electrode pads 41 of the support body 4 except for the third electrode pads 41A and 41E may be switched as appropriate in accordance with the positional relationship between the first chip 2 and the second chip 3. The configuration, operations, and effects of the example embodiment are otherwise the same as those of the first example embodiment.

### Fourth Example Embodiment

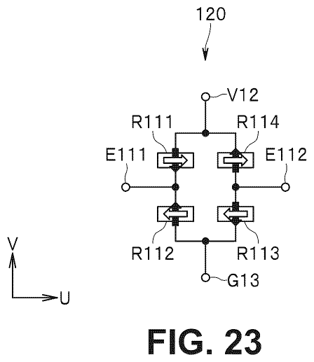

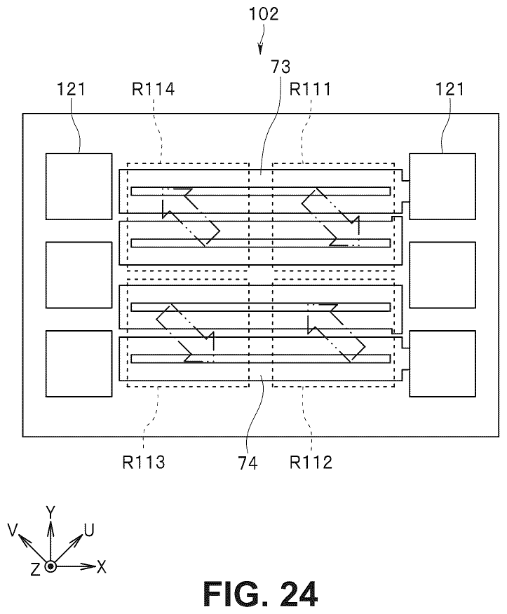

Next, with reference to FIG. 22 to FIG. 24, a fourth example embodiment of the disclosure is described. FIG. 22 is a plan view showing a magnetic sensor device 300 according to the example embodiment. FIG. 23 is a circuit diagram showing a circuit configuration of a second detection circuit 120 in the example embodiment. FIG. 24 is a plan view showing a part of a second chip 102 in the example embodiment,

In the example embodiment, in place of the second chip 3 in the first example embodiment in FIG. 2, the second chip 102 is provided. The magnetic sensor 1 includes the first chip 2 and the second chip 102. The configuration of the second chip 102 is basically the same as the configuration of the first chip 2. In other words, the second chip 102 has a rectangular solid shape. The second chip 102 has a top surface 102a and a bottom surface that are located opposite to each other, and four side surfaces connecting the top surface 102a and the bottom surface. The second chip 102 is mounted on the reference plane 4a in a posture such that the bottom surface of the second chip 102 faces the reference plane 4a of the support body 4.

The second chip 102 includes a plurality of second electrode pads 121 provided on a top surface 102a. In FIG. 22, the plurality of second electrode pads are denoted with the representative reference numeral 121. The plurality of second electrode pads 121 includes six second electrode pads similarly to the plurality of first electrode pads 21. In other words, the first chip 2 and the second chip 102 have the same type (common type) of chip structure (electrode pad structure).

As shown in FIG. 23, the second chip 102 includes the second detection circuit 120. The second detection circuit 120 is configured to detect a component of the target magnetic field in a direction parallel to the V direction and generate at least one second detection signal which has a correspondence with the component. The configuration of the second detection circuit 120 is basically the same as the first detection circuit 10 of the first chip 2. In other words, the second detection circuit 120 is a bridge circuits including the power supply port V12, a ground port G12, signal output ports E111 and E112, and the resistor sections R111, R112, R113, and R114. The plurality of MR elements 50 of the second detection circuit 120 (see FIG. 8) constitute the resistor sections R111, R112, R113, and R114.

The resistor section R111 is provided between the power supply port V12 and the signal output port E111. The resistor section R112 is provided between the signal output port E111 and the ground port G13. The resistor section R113 is provided between the signal output port E112 and the ground port G13. The resistor section R114 is provided between the power supply port V12 and the signal output port E112. A voltage or a current having a specific magnitude is applied to the power supply port V12. The ground port G12 is connected to the ground.

The second detection circuit 120 generates a signal corresponding to the electric potential of the signal output port E111 and a signal corresponding to the electric potential of the signal output port E112 as two second detection signals. The signal processing circuit 40 (see FIG. 3) is configured to the second detection value Sv based on the two second detection signals. The second detection value Sv is a detection value corresponding to the component of the target magnetic field in the direction parallel to the V direction.

FIG. 23, each of the resistor sections R111 to R114 is schematically represented by one MR element 50. In FIG. 23, solid arrows represent the magnetization directions of the magnetization pinned layers 52 of the MR elements 50 (see FIG. 8). Hollow arrows represent the magnetization directions of the free layers 54 of the MR elements 50 (see FIG. 8) in a case where no target magnetic field is applied to the MR elements 50.

In the example shown in FIG. 23, the magnetization directions of the magnetization pinned layers 52 of the MR elements 50 in each of the resistor sections R111 and R113 are the −V direction. The magnetization directions of the magnetization pinned layers of the MR elements 50 in each of the resistor sections R112 and R114 are the V direction. When the target magnetic field is not applied, the magnetization directions of the free layer 54 of the MR elements 50 in each of the resistor sections R111 and R114 are the U direction. When the target magnetic field is not applied, the magnetization directions of the free layer 54 of the MR elements 50 in each of the resistor sections R22 and R23 are the −U direction.

Hereinafter, the plurality of MR elements of the second detection circuit 120 may be referred to as a “plurality of second MR elements”.

As shown in FIG. 24, in the example embodiment, the magnetic sensor 1 includes a second coil group including two second coils 73 and 74 in place of the second coil group 80 in the first example embodiment. The second coil 73 is configured to apply a magnetic field to the MR elements 50 (the plurality of second MR elements) corresponding to the resistor sections R111 and R114. The second coil 74 is configured to apply a magnetic field to the MR elements 50 (the plurality of second MR elements) corresponding to the resistor sections R112 and R113. The second coil group is formed of a conductive material such as Cu.

Here, with reference to FIG. 24, the arrangement of the resistor sections R111 to R114 in the second chip 102 is described. In FIG. 24, the region in which the resistor section R111 is arranged is denoted with the reference numeral R111, the region in which the resistor section R112 is arranged is denoted with the reference numeral R112, the region in which the resistor section R113 is arranged is denoted with the reference numeral R113, and the region in which the resistor section R114 is arranged is denoted with the reference numeral R114. In the example shown in FIG. 24, the resistor sections R111 and R112 are arrayed in the stated order in the −Y direction. The resistor sections R113 and R114 are arranged in front of the resistor sections R112 and R111, respectively, in the −X direction.

The second coil 73 includes a plurality of coil parts, specifically, a coil part configured to generate a magnetic field in the first direction that is applied to the MR elements 50 (the plurality of second MR elements) corresponding to the resistor section R111 and a coil part configured to generate a magnetic field in the first direction that is applied to the MR elements 50 (the plurality of second MR elements) corresponding to the resistor section R114. The second coil 74 includes a plurality of coil parts, specifically, a coil part configured to generate a magnetic field in the second direction that is applied to the MR elements 50 (the plurality of second MR elements) corresponding to the resistor section R113 and a coil part configured to generate a magnetic field in the second direction that is applied to the MR elements 50 (the plurality of second MR elements) corresponding to the resistor section R112.

The second coil 73 and the second coil 74 are configured to apply magnetic fields in directions opposite to each other with respect to the MR elements 50 (the plurality of second MR elements). The second coil 73 applies a magnetic field in the −Y direction or the Y direction to the MR elements 50 (the plurality of second MR elements) corresponding to the resistor sections R111 and R114. The second coil 74 applies a magnetic field in the Y direction or the −Y direction to the MR elements 50 (the plurality of first MR elements) corresponding to the resistor sections R112 and R113.

The configuration, operations, and effects of the example embodiment are otherwise the same as those of the first example embodiment.

### Fifth Example Embodiment

FIG. 26 is a plan view showing a magnetic sensor device 400 in a fifth example embodiment of the disclosure. In the magnetic sensor device 400 shown in FIG. 26, the first chip 2 and the second chip 3 may not be provided in a divided manner but provided as a single chip (one chip) 103, and the single chip 103 may be supported by the support body 4. The single chip 103 provided with a plurality of electrode pads 131 obtained by integrating the first electrode pad 21 of the first chip 2 and the second electrode pads 31 of the second chip 3 is supported by the support body 4. The first chip 2 and the second chip 3 are not provided in a divided manner but provided as one chip. With this, the plurality of electrode pads 131 are not a simple sum of the first electrode pads 21 of the first chip 2 and the second electrode pads 31 of the second chip 3, and one coil terminal and one sensor terminal can be reduced (omitted) therefrom. The magnetic sensor device 400 includes a chip including a plurality of magnetoresistive elements, a support body that supports the chip, and a coil group including a plurality of coils configured to apply a magnetic field to the plurality of magnetoresistive elements. The support body includes the at least one power supply pad and the ground pad. The coil group includes the first end connected to the at least one power supply pad, and the second end located at an end opposite to the first end and connected to the ground pad. Further, the number of the at least one power supply pad is equal to or less than the total number of the plurality of coils.

In another viewpoint, the magnetic sensor device includes the support body that supports the chip, the coil group including the plurality of coils configured to apply a magnetic field to the plurality of magnetoresistive elements, and the plurality of bridge circuits configured with the plurality of magnetoresistive elements. The support body includes the plurality of first power supply pads for the plurality of bridge circuits, and the at least one second power supply pad for the coil group. Further, the number of the at least one second power supply pad is less than the number of the plurality of first power supply pads.

The magnetic sensor device of the disclosure can be achieved as a monolithic type in which the components (the first to third detection circuits 10, 20, and 30, the first and second electrode pads 21 and 31, the first and second coil groups 70 and 80, and the like) provided to the first chip 2 and the second chip 3 are provided to the support body 4 to obtain a single chip.

In the magnetic sensor device of the disclosure, the first coil group 70 and the second coil group 80 may be configured to generate alternating magnetic fields.

As described above, a magnetic sensor device according to an embodiment of the disclosure includes a first chip including a plurality of first magnetoresistive elements, a second chip including a plurality of second magnetoresistive elements, a support body that supports the first chip and the second chip, a first coil group including at least one first coil configured to apply a magnetic field to the plurality of first magnetoresistive elements, and a second coil group including at least one second coil configured to apply a magnetic field to the plurality of second magnetoresistive elements. The support body includes at least one power supply pad and a ground pad. The first coil group includes a first end connected to the at least one power supply pad, and a second end located at an end opposite to the first end. The second coil group includes a third end connected to the second end of the first coil group, and a fourth end located at an end opposite to the third end and connected to the ground pad. The number of the at least one power supply pad is equal to or less than the total number of the at least one first coil and the at least one second coil.

In the magnetic sensor device according to the embodiment of the disclosure, at least one of the at least one first coil and the at least one second coil may be a plurality of coils.

In the magnetic sensor device according to the embodiment of the disclosure, the plurality of coils may be connected in series.

In the magnetic sensor device according to the embodiment of the disclosure, the plurality of coils may include a coil configured to generate a magnetic field in a first direction and a coil configured to generate a magnetic field in a second direction.

In the magnetic sensor device according to the embodiment of the disclosure, the first coil group may be integrated with the first chip. The second coil group may be integrated with the second chip.

In the magnetic sensor device according to the embodiment of the disclosure, the second chip may include an electrode pad connected to the ground pad. The first chip may not include an electrode pad connected to the ground pad.

The magnetic sensor device according to the embodiment of the disclosure may further include a conductor that connects the second end of the first coil group and the third end of the second coil group to each other.

The magnetic sensor device according to the embodiment of the disclosure may further include a plurality of bridge circuits configured with the plurality of first magnetoresistive elements and the plurality of second magnetoresistive elements. The at least one power supply pad may be a plurality of power supply pads for the plurality of bridge circuits and one power supply pad for the first coil group and the second coil group.

In the magnetic sensor device according to the embodiment of the disclosure, the support body may include a signal processing circuit connected to the plurality of first magnetoresistive elements and the plurality of second magnetoresistive elements, and a driving circuit configured to drive the first coil group and the second coil group.

A magnetic sensor device according to an embodiment of the disclosure includes a chip including a plurality of magnetoresistive elements, a support body that supports the chip, and a coil group including a plurality of coils configured to apply a magnetic field to the plurality of magnetoresistive elements. The support body includes at least one power supply pad and a ground pad. The coil group includes a first end connected to the at least one power supply pad, and a second end located at an end opposite to the first end and connected to the ground pad. The number of the at least one power supply pad is equal to or less than the total number of the plurality of coils.

The magnetic sensor device according to the embodiment of the disclosure may further include at least one bridge circuit configured with the plurality of magnetoresistive elements. The at least one power supply pad may be at least one power supply pad for the at least one bridge circuit and one power supply pad for the coil group.

A magnetic sensor device according to an embodiment of the disclosure includes a support body that supports the chip, a coil group including a plurality of coils configured to apply a magnetic field to the plurality of magnetoresistive elements, and a plurality of bridge circuits configured with the plurality of magnetoresistive elements. The support body includes a plurality of first power supply pads for the plurality of bridge circuits, and at least one second power supply pad for the coil group. The number of the at least one second power supply pad is less than the number of the plurality of first power supply pads.

In the disclosure, the support body includes at least one power supply pad and a ground pad. The first coil group includes a first end connected to the at least one power supply pad, and a second end located at an end opposite to the first end. The second coil group includes a third end connected to the second end of the first coil group, and a fourth end located at an end opposite to the third end and connected to the ground pad. Further, the number of the at least one power supply pad is equal to or less than the total number of the at least one first coil and the at least one second coil. With this, according to the disclosure, it is possible to provide a magnetic sensor device that can achieve reduction in size and suitability for an operation under an environmental magnetic field.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A magnetic sensor device comprising:
a first chip including a plurality of first magnetoresistive elements;
a second chip including a plurality of second magnetoresistive elements;
a support body that supports the first chip and the second chip;
a first coil group including at least one first coil configured to apply a magnetic field to the plurality of first magnetoresistive elements; and
a second coil group including at least one second coil configured to apply a magnetic field to the plurality of second magnetoresistive elements, wherein
the support body includes:
at least one power supply pad; and
a ground pad,
the first coil group includes:
a first end connected to the at least one power supply pad; and
a second end located at an end opposite to the first end,
the second coil group includes:
a third end connected to the second end of the first coil group; and
a fourth end located at an end opposite to the third end and connected to the ground pad, and
the number of the at least one power supply pad is equal to or less than the total number of the at least one first coil and the at least one second coil.

2. The magnetic sensor device according to claim 1, wherein at least one of the at least one first coil and the at least one second coil is a plurality of coils.

3. The magnetic sensor device according to claim 2, wherein the plurality of coils are connected in series.

4. The magnetic sensor device according to claim 2, wherein the plurality of coils includes a coil configured to generate a magnetic field in a first direction and a coil configured to generate a magnetic field in a second direction.

5. The magnetic sensor device according to claim 1, wherein
the first coil group is integrated with the first chip, and
the second coil group is integrated with the second chip.

6. The magnetic sensor device according to claim 5, wherein
the second chip includes an electrode pad connected to the ground pad, and
the first chip does not include an electrode pad connected to the ground pad.

7. The magnetic sensor device according to claim 5, further comprising:
a conductor that connects the second end of the first coil group and the third end of the second coil group to each other.

8. The magnetic sensor device according to claim 1, further comprising:
a plurality of bridge circuits configured with the plurality of first magnetoresistive elements and the plurality of second magnetoresistive elements, wherein
the at least one power supply pad is a plurality of power supply pads for the plurality of bridge circuits and one power supply pad for the first coil group and the second coil group.

9. The magnetic sensor device according to claim 1, wherein
the support body includes:
a signal processing circuit connected to the plurality of first magnetoresistive elements and the plurality of second magnetoresistive elements; and
a driving circuit configured to drive the first coil group and the second coil group.

10. A magnetic sensor device comprising:
a chip including a plurality of magnetoresistive elements;
a support body that supports the chip; and
a coil group including a plurality of coils configured to apply a magnetic field to the plurality of magnetoresistive elements, wherein
the support body includes:
at least one power supply pad; and
a ground pad,
the coil group includes:
a first end connected to the at least one power supply pad; and
a second end located at an end opposite to the first end and connected to the ground pad, and
the number of the at least one power supply pad is equal to or less than the total number of the plurality of coils.

11. The magnetic sensor device according to claim 10, further comprising:
at least one bridge circuit configured with the plurality of magnetoresistive elements, wherein
the at least one power supply pad is at least one power supply pad for the at least one bridge circuit and one power supply pad for the coil group.

12. A magnetic sensor device comprising:
a chip including a plurality of magnetoresistive elements;
a support body that supports the chip;
a coil group including a plurality of coils configured to apply a magnetic field to the plurality of magnetoresistive elements; and
a plurality of bridge circuits configured with the plurality of magnetoresistive elements, wherein
the support body includes:
a plurality of first power supply pads for the plurality of bridge circuits; and
at least one second power supply pad for the coil group, and
the number of the at least one second power supply pad is less than the number of the plurality of first power supply pads.
